(19) United States
(12) Patent Application Publication
(10) Pub. No.: US 2021/0091297 A1
(43) Pub. Date: Mar. 25, 2021

(54) PIEZOELECTRIC SENSOR

(71) Applicant: FATRI (Xiamen) Technologies Co., Ltd., Xiamen City (CN)

(72) Inventors: Yongzhong NIE, Xiamen City (CN); Wenjie LIU, Xiamen City (CN)

(73) Assignee: FATRI (Xiamen) Technologies Co., Ltd., Xiamen City (CN)

(21) Appl. No.: 16/730,625

(22) Filed: Dec. 30, 2019

(30) Foreign Application Priority Data
Sep. 24, 2019 (CN) 201921593097.6

(51) Int. Cl. H01L 41/113; H01L 41/047; H01L 41/053; G01P 15/09; G01P 1/02

(52) U.S. Cl. CPC H01L 41/1132; H01L 41/0475; G01P 1/023; G01P 15/09; H01L 41/053

(57) ABSTRACT

The present disclosure relates to a piezoelectric sensor, and the piezoelectric sensor includes a support including a connecting member and a supporting member connected to one end of the connecting member; a piezoelectric element, formed as an annular member and disposed surrounding the connecting member; a mass, formed as an annular member and disposed surrounding the piezoelectric element; a first circuit board, disposed on the mass away from the supporting member and provided with a first circuit on a surface close to the mass; and a second circuit board, disposed on the first circuit board away from the supporting member and provided with a second circuit on a surface facing away from the first circuit board.

### CROSS REFERENCE TO RELATED APPLICATION

This application claims priority to Chinese Patent Application No. 201921593097.6, filed on Sep. 24, 2019, which is hereby incorporated by reference in its entirety.

### TECHNICAL FIELD

The present disclosure relates to a technical filed of sensors, and particularly to a piezoelectric sensor.

### BACKGROUND

A piezoelectric accelerometer, also known as a piezoelectric accelerometer, is an inertial sensor. The principle of the piezoelectric sensor lies in using the piezoelectric effect of a piezoelectric element. When the accelerometer is vibrated, a force applied to the piezoelectric element by a mass changes. When the measured vibration frequency is much lower than a natural frequency of the accelerometer, the change of the force is proportional to the measured acceleration.

However, the existing piezoelectric sensors cannot have a compact structure and an output of high sensitivity at the same time.

### SUMMARY

The object of the embodiments of the present disclosure is to provide a piezoelectric sensor, which has a compact structure and meanwhile has an output of high sensitivity.

On one aspect, the embodiments of the present disclosure provide a piezoelectric sensor, including a support, including a connecting member and a supporting member connected to one end of the connecting member; a piezoelectric element, formed as an annular member and disposed surrounding the connecting member; a mass, formed as an annular member and disposed surrounding the piezoelectric element; a first circuit board, disposed on the mass away from the supporting member and provided with a first circuit on a surface close to the mass; and a second circuit board, disposed on the first circuit board away from the supporting member and provided with a second circuit on a surface facing away from the first circuit board.

According to one aspect of the present disclosure, the first circuit is embedded within the first circuit board.

According to one aspect of the present disclosure, the first circuit is disposed corresponding to a central hollow region of the mass on the first circuit board.

According to one aspect of the present disclosure, the first circuit board is provided with a first recess recessed inwardly from an outer peripheral surface of the first circuit board.

According to one aspect of the present disclosure, the second circuit board is provided with a second recess recessed inwardly from an outer peripheral surface of the second circuit board.

According to one aspect of the present disclosure, the first recess and the second recess are aligned with each other in an axial direction of the first circuit board.

According to one aspect of the present disclosure, the first recess or the second recess is a flat recess.

According to one aspect of the present disclosure, the piezoelectric sensor further includes a housing, including an internal cavity and a support opening, wherein the supporting member of the support is connected to the housing at the support opening, and the piezoelectric element, the mass, the first circuit board and the second circuit board are disposed in the internal cavity of the housing.

According to one aspect of the present disclosure, the housing further includes a connector opening at which a connector is disposed, wherein the first recess or the second recess is disposed toward the connector opening.

According to one aspect of the present disclosure, wherein the first circuit board and the second circuit board are integrally formed.

### BRIEF DESCRIPTION OF THE DRAWINGS

Other features, objects, and advantages of the present disclosure will be more apparent from the following detailed description of the non-limiting embodiments by referring to the drawings, wherein the same or similar reference numerals designate the same or similar features, and the drawings are not drawn to scale.

FIG. 1 is a cross-sectional view showing a configuration of a piezoelectric sensor according to an embodiment of the present disclosure;

FIG. 2 is a cross-sectional view of a first circuit board and a second circuit board according to one embodiment;

FIG. 3 is a cross-sectional top view of a first circuit board and a second circuit board according to one embodiment;

FIG. 4 is a cross-sectional top view of a first circuit board and a second circuit board according to another embodiment;

FIG. 5 is a cross-sectional view showing a configuration of a piezoelectric sensor according to another embodiment of the present disclosure.

### DESCRIPTION OF REFERENCE NUMERALS

1—support;
2—piezoelectric element;
3—mass;
41—first circuit board; 411—first recess;
42—second circuit board; 421—second recess;
5—housing;
6—connector.

### DETAILED DESCRIPTION

Below, various aspects and exemplary embodiments of the present disclosure will be described in detail. In order to clearly show the objects, technical solutions and advantages of the present disclosure, the present disclosure is further described in detail below with reference to the drawings and embodiments. It should be understood that, the described embodiments are intended to explain the present disclosure, and are not intended to limit the scope of the present disclosure. For the person skilled in the art, the present disclosure may be practiced without some of the details of these specific details. The following description of the embodiments is merely used to provide a better understanding of the present disclosure in a manner of illustrating examples of the present disclosure.

It should be noted that, in this context, relational terms such as “first” and “second” are used merely to distinguish one entity or operation from another entity or operation, and do not necessarily require or imply any actual relationship or order between the entities or operations. Further, terms “include”, “comprise” or any other variations thereof are intended to encompass a non-exclusive inclusion, such that a process, method, article, or device including a plurality of elements, includes not only the plurality of elements, but also other elements not specifically listed, or other elements that are inherent to such a process, method, article, or device. The element that is defined by the phrase “includes” without other limitations, does not exclude the presence of additional identical elements in the process, method, article, or device including this element.

It should be understood that when describing a structure of a component, if a layer or a region is referred to as being “above” or “on” another layer or another region, it may mean that the layer or the region is directly on another layer or another region, or mean that there is other layer or region between the layer or the region and another layer or another region. Moreover, if the component is reversed, the layer or the region will be located “under” or “below” another layer or another region.

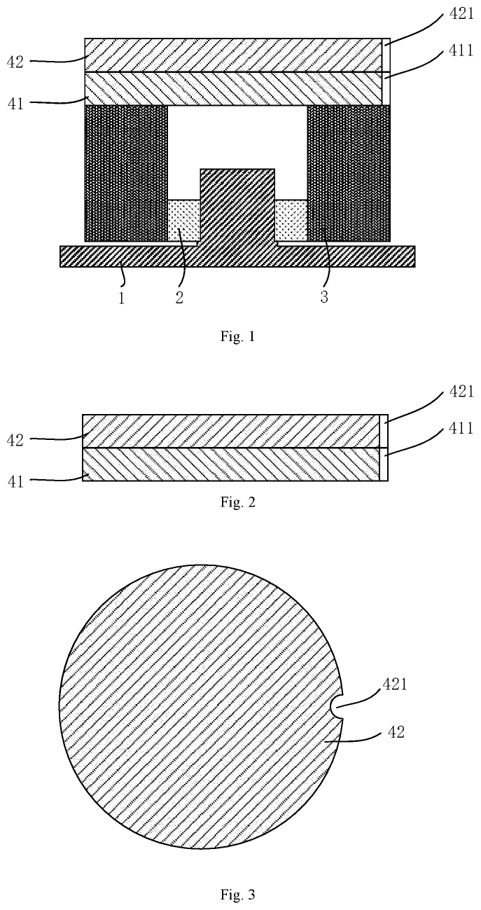

FIG. 1 is a cross-sectional view showing a configuration of a piezoelectric sensor according to one embodiment of the present disclosure. Referring to FIG. 1, a piezoelectric sensor according to an embodiment of the present disclosure includes a support 1, a piezoelectric element 2, a mass 3, and a circuit board. Further, the circuit board includes a first circuit board 41 and a second circuit board 42.

The support 1 includes a connecting member and a supporting member connected to one end of the connecting member. The connecting member is substantially formed in a columnar shape and has two ends opposite to each other in an axial direction and an outer peripheral surface between the two ends. In a specific embodiment, the connecting member is formed in a cylindrical shape. It can be understood that the connecting member may be formed in a shape of polygon prism, and further may be formed as a column constituted by a plurality of columns with different diameters. The supporting member is substantially formed in a shape of disc, and is connected to one end of the connecting member. Preferably, the connecting member is connected to a central portion of the supporting member. The connecting member and the supporting member may be integrally formed. A boss may be formed between the connecting member and the supporting member, which is located at a joint of the connecting member and the supporting member and includes a stepped surface facing away from the supporting member. The boss has an outer diameter larger than a diameter of the connecting member and smaller than a diameter of the supporting member.

The piezoelectric element 2 is formed as an annular member and disposed surrounding the connecting member. The piezoelectric element 2 is made of a piezoelectric material, for example, a piezoelectric ceramic. The piezoelectric element 2 includes an inner surface and an outer surface opposite to each other in a radial direction. The inner surface of the piezoelectric element 2 is contacted with and connected to the outer peripheral surface of the connecting member. The piezoelectric element 2 and the connecting member may be connected to each other by an adhesive or by a manner of expansion. In the embodiment in which the support 1 includes a boss, the piezoelectric element 2 is disposed on the stepped surface of the boss, that is, one end surface of the piezoelectric element 2 is in contact with the stepped surface. The piezoelectric element 2 does not contact the supporting member.

The mass 3 is formed as an annular member, and disposed surrounding the piezoelectric element 2. The mass 3 is a member with a density larger than that of the piezoelectric element 2. The mass 3 may be made of a material with a relatively large density, such as a metal alloy. In a specific embodiment, the mass 3 is made of a tungsten-copper alloy. The mass 3 includes an inner surface and an outer surface opposite to each other in a radial direction. The inner surface of the mass 3 is contacted with and connected to the outer surface of the piezoelectric element 2. The mass 3 and the piezoelectric element 2 may be connected to each other by an adhesive or by a manner of expansion. The mass 3 does not contact the supporting member. An end surface of the mass 3 facing the supporting member is flush with an end surface of the piezoelectric element 2 facing the supporting member. The mass 3 has an axial height greater than that of the piezoelectric element 2. In a preferred embodiment, the axial height of the mass 3 is more than three times the axial height of the piezoelectric element 2. In an alternative embodiment, the mass 3 has a maximum outer diameter more than twice that of the piezoelectric element 2.

The first circuit board 41 is disposed on the mass 3 away from the supporting member, and is provided with a first circuit on a surface close to the mass 3. The first circuit board 41 is substantially formed in a shape of disc, and preferably is circular. The first circuit board 41 has a diameter equal to or smaller than the maximum outer diameter of the mass 3. In a preferred embodiment, the diameter of the first circuit board 41 is equal to the maximum outer diameter of the mass 3. The first circuit may be a patterned circuit laid on the surface of the first circuit board 41. In some alternative implementations, the first circuit is embedded within the first circuit board 41. In some alternative embodiments, the first circuit has a projection, on the supporting member of the support 1, partially overlapped with end surfaces of the mass 3. Since the first circuit is embedded within the first circuit board 41, the first circuit can be isolated from the mass 3. Meanwhile, the first circuit can fully utilize an area of the first circuit board 41, and thus can maximize a circuit area thereof. In some other alternative embodiments, the first circuit is disposed corresponding to a central hollow region of the mass 3 on the first circuit board 41. That is, the projection of the first circuit on the supporting member of the support 1 does not overlap with the end surfaces of the mass 3. As such, the mass 3 can be prevented from affecting the first circuit and a reliability of the circuit can be improved.

The second circuit board 42 is disposed on the first circuit board 41 away from the supporting member, and is provided with a second circuit on a surface facing away from the first circuit board 41. The second circuit board 42 is substantially formed in a shape of disc, and is preferably circular. The second circuit board 42 has a diameter equal to or smaller than the maximum outer diameter of the mass 3. In a preferred embodiment, the diameter of the second circuit board 42 is equal to the maximum outer diameter of the mass 3. Preferably, the diameter of the second circuit board 42 is equal to the diameter of the first circuit board 41. The second circuit may be a patterned circuit laid on the surface of the second circuit board 42. In an alternative embodiment, the second circuit is embedded within the second circuit board 42. The second circuit of the second circuit board 42 may be electrically connected to the first circuit of the first circuit board 41. The second circuit may be electrically connected to the first circuit by a wire.

The piezoelectric sensor according to an embodiment of the present disclosure includes a first circuit board 41 and a second circuit board 42 disposed one on top of another, and the first circuit board 41 and the second circuit board 42 are respectively provided with the respective circuits. Therefore, a lateral dimension of the piezoelectric sensor can be reduced while a relatively large circuit area can be provided, thereby generating a compact structure of the piezoelectric sensor with an output of high sensitivity. Further, the circuits are respectively disposed on one surface of the first circuit board 41 and the second circuit board 42, that is, the circuit is provided on a single surface of the circuit board, the process for forming such circuit is simple and mature, and is easy to implement.

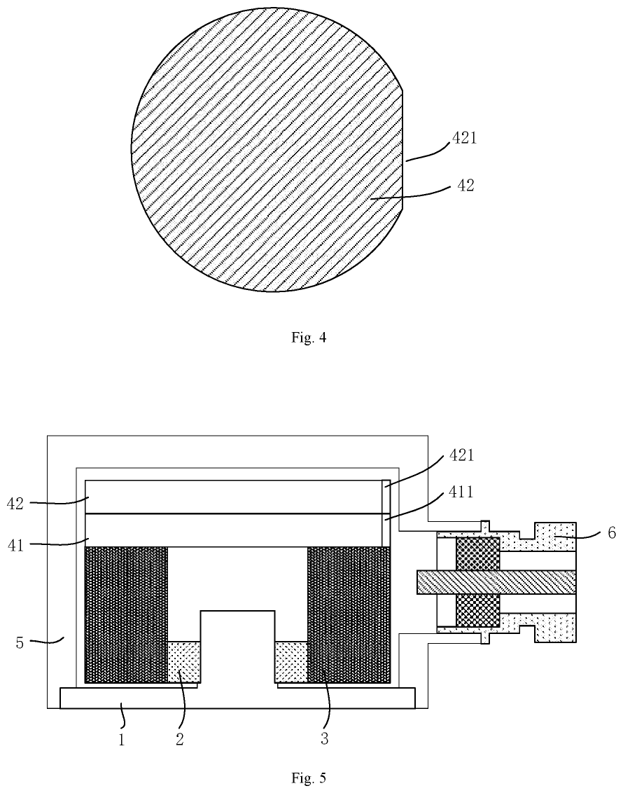

Referring to FIG. 2 and FIG. 3 together, FIG. 2 shows a cross-sectional view of a first circuit board and a second circuit board according to one embodiment, and FIG. 3 shows a cross-sectional top view of a first circuit board and a second circuit board according to one embodiment.

In some alternative embodiments, the second circuit board 42 is provided with a second recess 421 that is recessed inwardly from an outer peripheral surface of the second circuit board 42. The second recess 421 is formed as a through-groove and penetrates two end surfaces opposite to each other of the second circuit board 42, such that an electrical connection member (e.g. a wire) drawn from the second circuit of the second circuit board 42 may be arranged and extended in the second recess 421. As such, there is no need to provide a wiring space outside the second circuit board 42, and a gap between the second circuit board 42 and other components can be reduced, thereby making the structure of the piezoelectric sensor according to the embodiment of the present disclosure to be more compact.

In some alternative embodiments, the first circuit board 41 is provided with a first recess 411 that is recessed inwardly from an outer peripheral surface of the first circuit board 41. The first recess 411 is formed as a through-groove and penetrates two end surfaces opposite to each other of the first circuit board 41, such that an electrical connection member (e.g. a wire) drawn from the first circuit of the first circuit board 41 may be arranged and extended in the first recess 411. As such, there is no need to provide a wiring space outside the first circuit board 41, and a gap between the first circuit board 41 and other components can be reduced, thereby making the structure of the piezoelectric sensor according to the embodiment of the present disclosure to be more compact.

It can be understood that the second recess 421 of the second circuit board 42 and the first recess 411 of the first circuit board 41 can be disposed independently to reduce the additional wiring space. That is, in the case where a space outside of the first circuit board 41 or the second circuit board 42 is sufficient, only the first recess 411 or the second recess 421 may be provided correspondingly. In a preferred embodiment, both of the second recess 421 of the second circuit board 42 and the first recess 411 of the first circuit board 41 are provided. In some alternative embodiments, the first recess 411 and the second recess 421 are aligned in an axial direction of the first circuit board 41. In this case, the wiring of the electrical connection members (e.g., wire) arranged in the first recess 411 and the second recess 421 is the simplest, with a shortest wiring path. As a result, material can be saved, and reliability can be increased. The first recess 411 may have a dimension the same as that of the second recess 421. It can be understood that the first recess 411 and the second recess 421 may be staggered or may have different dimensions, considering positional and dimensional limits of other components or particular circuit arrangement requirements.

Referring to FIG. 4, FIG. 4 is a cross-sectional top view of a first circuit board and a second circuit board according to another embodiment.

In some alternative embodiments, the first recess 411 or the second recess 421 is formed as a flat recess. That is, the first recess 411 is formed as a flat surface on the outer peripheral surface of the first circuit board 41, or the second recess 421 is formed as a flat surface on the outer peripheral surface of the second circuit board 42. The flat recess is easy to machine and the wiring is more free with such recess. In a preferred embodiment, both of the first recess 411 and the second recess 421 are flat recesses. In a further preferred embodiment, the first recess 411 and the second indentation 421 are both flat recesses and meanwhile aligned with each other in the axial direction of the first circuit board 41.

In some alternative embodiments, the first circuit board 41 and the second circuit board 42 are integrally formed. That is, the first circuit board 41 and the second circuit board 42 are formed into one single circuit board, and the first circuit and the second circuit are respectively disposed on two opposite end surfaces of the circuit board. As such, the circuit board can be set thinner.

Referring to FIG. 5 together, FIG. 5 is a cross-sectional view showing a configuration of a piezoelectric sensor according to another embodiment of the present disclosure.

In some alternative embodiments, the piezoelectric sensor according to an embodiment of the present disclosure further includes a housing 5, which includes an internal cavity and a support opening, wherein the supporting member of the support 1 is connected to the housing 5 at the support opening, and the piezoelectric element 2, the mass 3, the first circuit board 41 and the second circuit board 42 are disposed in the internal cavity of the housing 5. The housing 5 may have an outer contour in a shape of cylinder, polyhedron, polygonal prism, etc. Preferably, the outer contour of the housing 5 is in a tetrahedral shape, and since an outer peripheral surface of the housing 5 has a side plane, the piezoelectric sensor according to an embodiment of the present disclosure can be installed by use of the side plane, for example, by bonding, with an installation surface perpendicular to a surface to be tested. The internal cavity of the housing 5 may have a profile corresponding to outer profiles of the mass 3, the first circuit board 41 and the second circuit board 42. In a preferred embodiment, the internal cavity of the housing 5 has a cylindrical profile. In the case where the housing 5 is not in contact with the mass 3, the first circuit board 41, and the second circuit board 42, a gap between the housing 5 and the mass 3, the first circuit board 41, and the second circuit board 42 may be set to be extremely small, to further compact the structure of the piezoelectric sensor. The support opening of the housing 5 may be circular and sized to match that of the supporting member of the support 1, such that the supporting member may be capped to the support opening. The support opening may be provided at a bottom of the housing 5.

In some alternative embodiments, the housing 5 further includes a connector opening at which a connector 6 is disposed, and the first recess 411 or the second recess 421 is disposed toward the connector opening. The connector opening is opened in an orientation different from the support opening. In an alternative embodiment, the connector opening can be provided at a side wall of the housing 5. Since the connector opening enables a certain additional space for the internal cavity of the housing 5, the additional space can be fully utilized for wiring by disposing the first recess 411 or the second recess 421 toward the connector opening.

It shall be understood that the specific embodiments of the present disclosure described in the specification are illustrative, and should not be construed as limiting the scope of the present disclosure. The protective scope of the present disclosure is defined by the claims, and covers all the embodiments falling within the scope thereof and obvious equivalents thereof.

What is claimed is:

1. A piezoelectric sensor, comprising:
a support, comprising a connecting member and a supporting member connected to one end of the connecting member;
a piezoelectric element, formed as an annular member and disposed surrounding the connecting member;
a mass, formed as an annular member and disposed surrounding the piezoelectric element;
a first circuit board, disposed on the mass away from the supporting member and provided with a first circuit on a surface close to the mass; and
a second circuit board, disposed on the first circuit board away from the supporting member and provided with a second circuit on a surface facing away from the first circuit board.

2. The piezoelectric sensor according to claim 1, wherein the first circuit is embedded within the first circuit board.

3. The piezoelectric sensor according to claim 1, wherein the first circuit is disposed corresponding to a central hollow region of the mass on the first circuit board.

4. The piezoelectric sensor according to claim 1, wherein the first circuit board is provided with a first recess recessed inwardly from an outer peripheral surface of the first circuit board.

5. The piezoelectric sensor according to claim 4, wherein the second circuit board is provided with a second recess recessed inwardly from an outer peripheral surface of the second circuit board.

6. The piezoelectric sensor according to claim 5, wherein the first recess and the second recess are aligned with each other in an axial direction of the first circuit board.

7. The piezoelectric sensor according to claim 5, wherein at least one of the first recess and the second recess is a flat recess.

8. The piezoelectric sensor according to claim 1, further comprises a housing, comprising an internal cavity and a support opening, wherein the supporting member of the support is connected to the housing at the support opening, and the piezoelectric element, the mass, the first circuit board and the second circuit board are disposed in the internal cavity of the housing.

9. The piezoelectric sensor according to claim 8, wherein the housing further comprises a connector opening, at which a connector is disposed.

10. The piezoelectric sensor according to claim 9, wherein the first circuit board is provided with a first recess recessed inwardly from an outer peripheral surface of the first circuit board, and the second circuit board is provided with a second recess recessed inwardly from an outer peripheral surface of the second circuit board, wherein at least one of the first recess and the second recess is disposed toward the connector opening.

11. The piezoelectric sensor according to claim 1, wherein the first circuit board and the second circuit board are integrally formed.
